(19) United States
(12) Patent Application Publication
(10) Pub. No.: US 2026/0090052 A1
(43) Pub. Date: Mar. 26, 2026

(54) SEMICONDUCTOR STRUCTURE AND MANUFACTURING METHOD THEREOF

(71) Applicant: Taiwan Semiconductor Manufacturing Company, Ltd., Hsinchu (TW)

(72) Inventors: Shih-Cheng CHEN, Hsinchu (TW); Wen-Ting LAN, Hsinchu (TW); Jung-Hung CHANG, Hsinchu (TW); Chia-Cheng TSAI, Hsinchu (TW); Kuo-Cheng CHIANG, Hsinchu (TW)

(73) Assignee: Taiwan Semiconductor Manufacturing Company, Ltd., Hsinchu (TW)

(21) Appl. No.: 18/896,187

(22) Filed: Sep. 25, 2024

(51) Int. Cl. H01L 29/66; H01L 21/8234; H01L 27/088; H01L 29/06; H01L 29/423; H01L 29/775; H01L 29/786

(52) U.S. Cl. CPC H10D 64/018; H10D 30/014; H10D 30/43; H10D 30/6735; H10D 30/6757; H10D 62/115; H10D 62/121; H10D 64/017; H10D 84/0128; H10D 84/0151; H10D 84/038; H10D 84/83

(57) ABSTRACT

A semiconductor structure includes a substrate, plurality of active channels, a metal gate, a plurality of inner spacers and a first isolation layer. The substrate has an upper surface and a recess recessed relative to the upper surface. The active channels are vertically stacked on the upper surface of the substrate. The metal gate is disposed on the active channels. The inner spacers are disposed on a lateral surface of the metal gate. The first isolation layer is disposed within the recess and connected with the bottommost inner spacer. The first isolation layer protrudes relative to the upper surface of the substrate.

### BACKGROUND

As device scaling down, OD space will be reduced and the isolation between a source epitaxy and a drain epitaxy will be a big issue (for example. current leakage). In addition, in small OD space, due to the small space inducing non-efficient INSP (inner spacer) trim, the INSP random residue is observed at the small OD width. The INSP residue will induce worse semiconductor region (L0 EPI) raise height control.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1A_a illustrates a schematic diagram of a cross-sectional view of a first local portion P1 of a semiconductor structure 100 along a X-Z plane according to an embodiment of the present disclosure;

FIG. 1A_b illustrates a schematic diagram of a cross-sectional view of the first local portion P1 of the semiconductor structure 100 along a Y-Z plane;

FIG. 1B_a illustrates a schematic diagram of a cross-sectional view of a second local portion P2 of a semiconductor structure 100 along the X-Z plane;

FIG. 1B_b illustrates a schematic diagram of a cross-sectional view of the second local portion P2 of the semiconductor structure 100 along the Y-Z plane; and

FIG. 2A_a to 15B_b illustrate schematic diagrams of manufacturing processes of the semiconductor structure 100 in FIG. 1A_a to 1B_b.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

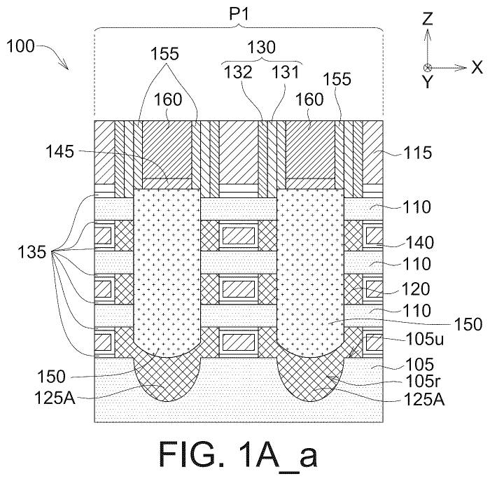

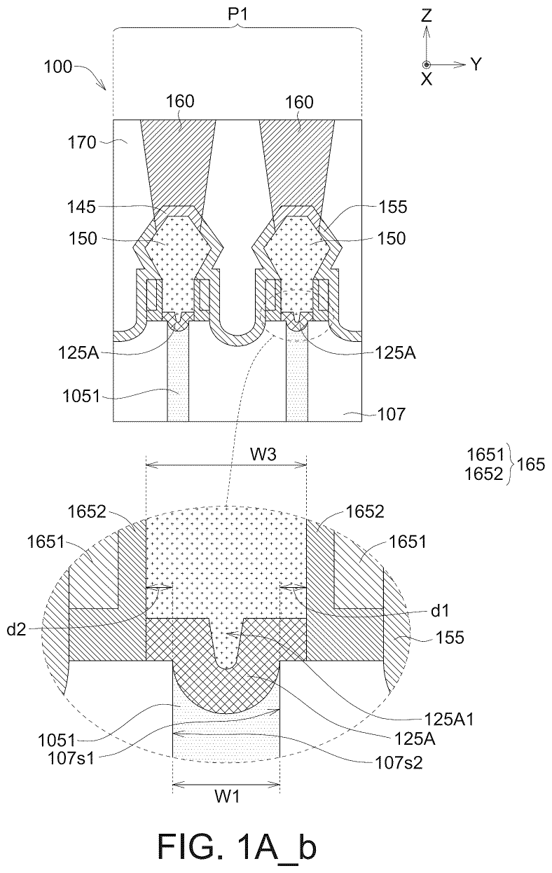

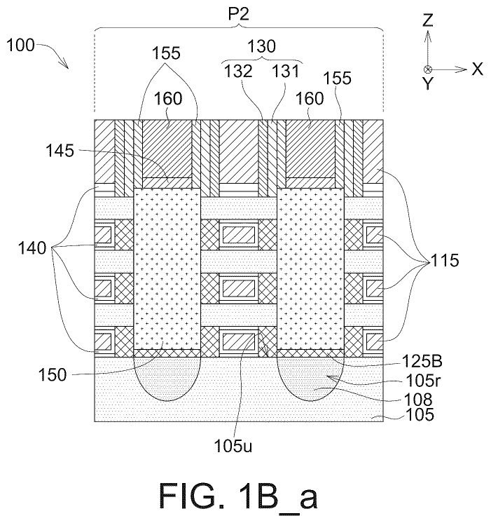

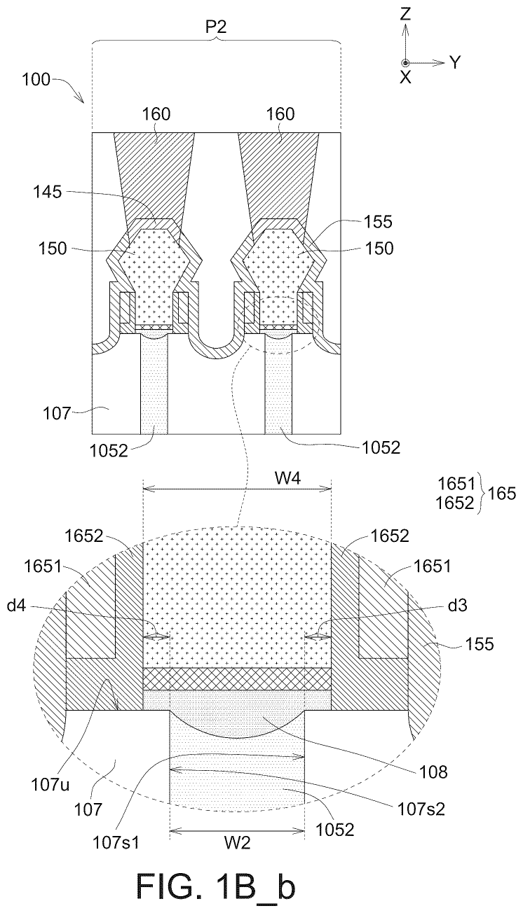

As illustrated in FIG. 1A_a to 1B_b, FIG. 1A_a illustrates a schematic diagram of a cross-sectional view of a first local portion P1 of a semiconductor structure 100 along a X-Z plane according to an embodiment of the present disclosure, FIG. 1A_b illustrates a schematic diagram of a cross-sectional view of the first local portion P1 of the semiconductor structure 100 along a Y-Z plane, FIG. 1B_a illustrates a schematic diagram of a cross-sectional view of a second local portion P2 of a semiconductor structure 100 along the X-Z plane, FIG. 1B_b illustrates a schematic diagram of a cross-sectional view of the second local portion P2 of the semiconductor structure 100 along the Y-Z plane.

As illustrated in FIG. 1A_a to 1B_b, the semiconductor structure 100 includes a substrate 105, an oxide layer 107, a semiconductor region 108, a plurality of active channels 110, a plurality of metal gate 115, a plurality of inner spacer 120, a plurality of first isolation layers 125A, a plurality of second isolation layers 125B, a plurality of second spacers 130, a plurality of first dielectric layer 135, a plurality of second dielectric layer 140, a silicide layer 145, a plurality of epitaxies 150, a plurality of contact etching stop layers (CESL) 155, a plurality of contacts 160, a plurality of first spacers 165 and an interlayer dielectric (ILD) 170.

As illustrated in FIG. 1A_a to 1B_b, the substrate 105 is, for example, a portion of a silicon wafer. The substrate 105 includes at least one first oxide definition (OD) region 1051 and at least one second OD region 1052. The OD region extends in X-axis. In the first local portion P1 of the semiconductor structure 100 (as illustrated in 1A_a to 1A_b), the first OD region 1051 has a first width W1. In the second local portion P2 of the semiconductor structure 100 (as illustrated in 1B_a to 1B_b), the second OD region 1052 has a second width W2. The first width W1 is different from the second width W2. For example, the first width W1 is less than the second width W2. In an embodiment, the first width W1 is, for example, equal to or less than 10 nanometers (nm), and the second width W2 is, for example, greater than 10 nm, 11 nm, 12 nm, or even greater. The oxide layer 107 is formed on adjacent two lateral surfaces of the first OD region 1051 and adjacent two lateral surfaces of the second OD region 1052. In an embodiment, the oxide layer 107 is, for example, a Shallow Trench Isolation (STI). The active channels 110 may be formed of, for example, silicon. The active channel 110 may be called “nanosheet”.

In the first local portion P1 of the semiconductor structure 100, as illustrated in 1A_a to 1A_b, the substrate 105 has an upper surface 105u and a recess 105r recessed relative to the upper surface 105u. The active channels 110 are stacked in a direction Z. The metal gate 115 is disposed on the active channel 110. The inner spacer 120 is disposed a lateral surface of the metal gate 115. The first isolation layer 125A is disposed within the recess 105r and connected with the inner spacer 120. The first isolation layer 125A protrudes relative to the upper surface 105u of the substrate 105. The first isolation layer 125A may increase the capacitance between the adjacent two of the epitaxies 150, and accordingly it may increase AC performance and/or the isolation between the adjacent two of the epitaxies 150 (reducing the current leakage). The first isolation layer 125A is disposed over the first OD region 1051 and has an upper surface 125Au and a slot 125A1 extending from the upper surface 125Au of the first isolation layer 125A toward the first OD region 1051. Due to the slot 125A1 is narrow enough, the first isolation layer 125A may be retained after an etching process for the first isolation layer material. In addition, the epitaxy 150 may be formed over the first isolation layer 125A and fill the slot 125A1. The first isolation layer 125A herein may be called “Flexible Bottom Dielectric (FBI)”.

In the second local portion P2 of the semiconductor structure 100, as illustrated in 1B_a to 1B_b, the semiconductor region 108 may be formed of, for example, silicon (for example, L0 Epitaxy), SiGe, dielectric layer such as SiO2, SiN, etc. The semiconductor region 108 is disposed within the recess 105r, above the second OD region 1052 and protrudes relative to an upper surface 107u of the oxide layer 107. The second isolation layer 125B is disposed over the semiconductor region 108, and protrudes relative to the upper surface 105u of the substrate 105 and the upper surface 107u of the oxide layer 107. The second isolation layer 125B may increase the capacitance between the adjacent two of the epitaxies 150, and accordingly it may increase AC performance and/or the isolation between the adjacent two of the epitaxies 150 (reducing the current leakage). In addition, the oxide layer 107 further has a first lateral surface 107s1 and a second lateral surface 107s2 opposite to the first lateral surface 107s1. The first lateral surface 107s1 and the second lateral surface 107s2 face the second OD region 1052. The second isolation layer 125B protrudes relative to the upper surface 107u of the oxide layer 107. The second isolation layer 125B may be contact with a first portion 1652 of the first spacer 165. The first spacer 165 is disposed on the upper surface 107u of the oxide layer 107, and the other of the opposite two first portions 1652 of the first spacer 165 is spaced from the second lateral surface 107s2 of the oxide layer 107 by a distance. The second isolation layer 125B herein may be called “Flexible Bottom Dielectric (FBI)”.

As illustrated in FIG. 1A_b, in the first local portion P1, two first portions 1652 which are located at opposite two sides of the first isolation layer 125A are spaced from each other by a third width W3, and the third width W3 is greater than the first width W1. A difference between the opposite two first portions 1652 ranges between 2 micrometers (μm) and 8 μm. One of the opposite two first portions 1652 of the first spacer 165 is spaced from the first lateral surface 107s1 of the oxide layer 107 by a first distance d1, the first distance d1 may range between 1 μm and 4 μm. The other of the opposite two first portions 1652 of the first spacer 165 is spaced from the second lateral surface 107s2 of the oxide layer 107 by a second distance d2, the second distance d2 may range between 1 μm and 4 μm.

As illustrated in FIG. 1B_b, in the second local portion P2, two first portions 1652 which are located at opposite two sides of the second isolation layer 125B are spaced from each other by a fourth width W4, and the fourth width W4 is greater than the second width W2. A difference between the opposite two first portions 1652 ranges between 2 μm and 8 μm. One of the opposite two first portions 1652 of the first spacer 165 is spaced from the first lateral surface 107s1 of the oxide layer 107 by a third distance d3, the third distance d3 may range between 1 μm and 4 μm. The other of the opposite two first portions 1652 of the first spacer 165 is spaced from the second lateral surface 107s2 of the oxide layer 107 by a fourth distance d4, the fourth distance d4 may range between 1 μm and 4 μm.

Regardless of whether the width of the OD region is large (for example, the second OD region 1052 in FIG. 1B_b) or small (for example, the first OD region 1051 in FIG. 1A_b), the isolation layer (the first isolation layer 125A and the second isolation layer 125B) capable of increasing the isolation between the adjacent two of the epitaxies 150 may be formed above the OD region.

As illustrated in FIG. 1A_a to 1A_b, the first isolation layer 125A and the inner spacer 120 may be formed of the same material including, for example, SiOCN, SiOC, SiCN, etc. In addition, the first isolation layer 125A and the inner spacer 120 may be formed in the same manufacturing process (see FIG. 5A_a). As illustrated in 1B_a to 1B_b, the second isolation layer 125B may be formed of a material including, for example, SiN, SiCN, SiOCN, etc.

As illustrated in FIG. 1A_a and 1B_a, the first dielectric layers 135 are formed on the active channels 110, and the second dielectric layers 140 over the first dielectric layers 135 and the inner spacer 120 are formed by using, for example, deposition. In an embodiment, the first dielectric layers 135 is, for example, an interface layer IL, and the second dielectric layers 140 is, for example, High-k gate dielectric layer.

The High-k gate dielectric layer HK may be formed of a material including: (i) a high-k dielectric material, such as hafnium oxide (HfO₂), titanium oxide (TiO₂), hafnium zirconium oxide (HfZrO), tantalum oxide (Ta₂O₃), hafnium silicate (HfSiO₄), zirconium oxide (ZrO₂), and zirconium silicate (ZrSiO₂), and (ii) a high-k dielectric material having oxides of lithium (Li), beryllium (Be), magnesium (Mg), calcium (Ca), strontium (Sr), scandium (Sc), yttrium (Y), zirconium (Zr), aluminum (Al), lanthanum (La), cerium (Ce), praseodymium (Pr), neodymium (Nd), samarium (Sm), europium (Eu), gadolinium (Gd), terbium (Tb), dysprosium (Dy), holmium (Ho), erbium (Er), thulium (Tm), ytterbium (Yb), lutetium (Lu), (iii) other suitable high-k dielectric materials, or (iv) a combination thereof. As used herein, the term “high-k” refers to a high dielectric constant. In the field of semiconductor device structures and manufacturing processes, high-k refers to a dielectric constant that is greater than the dielectric constant of SiO₂ (e.g., greater than 3.9).

As illustrated in FIG. 1A_a to 1B_b, the first spacer 165 includes the second portion 1651 and the first portion 1652. The first portion 1652 is disposed between the first isolation layer 125A and the second portion 1651. The second spacer 130 includes a second portion 131 and a first portion 132. The first portion 132 is disposed between the metal gate 115 and the second portion 131. In an embodiment, the second portion 131 may be formed a material same as that of the second portion 1651, and the first portion 132 may be formed a material same as that of the first portion 1652. The second portion 131 may be formed of a material different from that of the first portion 132, and the second portion 1651 may be formed of a material different from that of the first portion 1652. In terms of material, the second portion 131 may be formed of one of SiO, SiN, SiOC, SiON, SiOCN, etc., the first portion 132 may be formed of another of SiO, SiN, SiOC, SiON, SiOCN, etc. In addition, the ILD 170 is formed over the CESL 155.

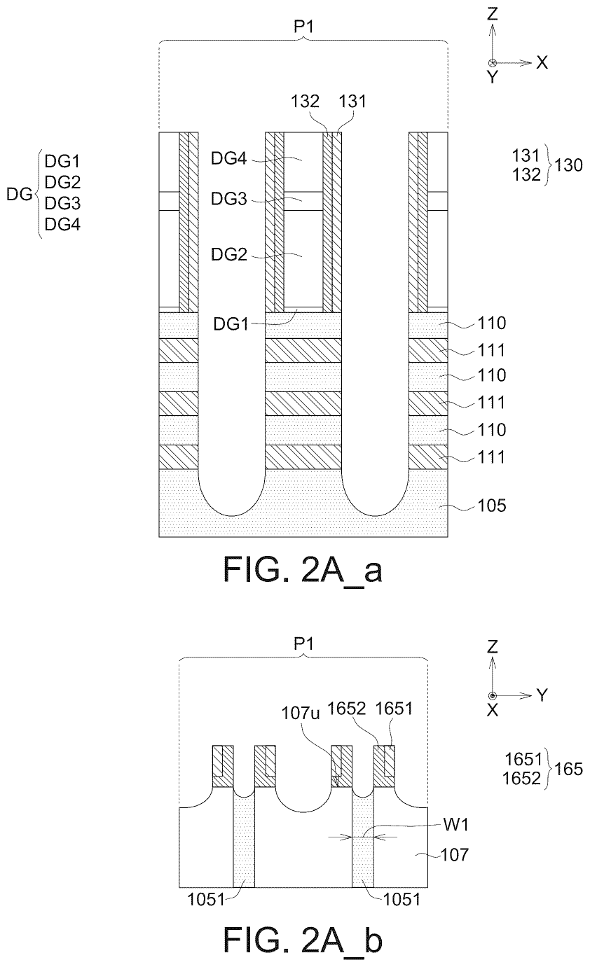

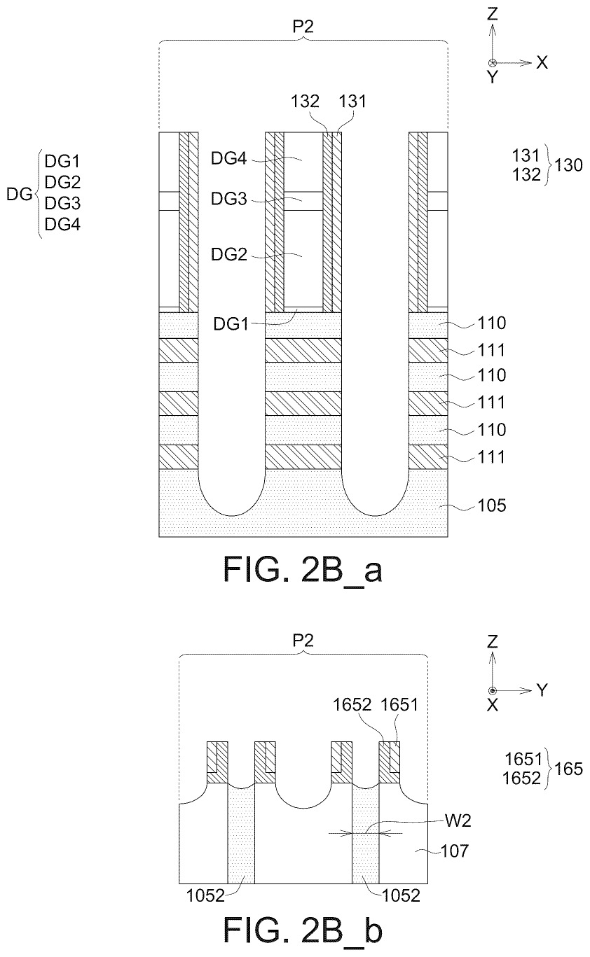

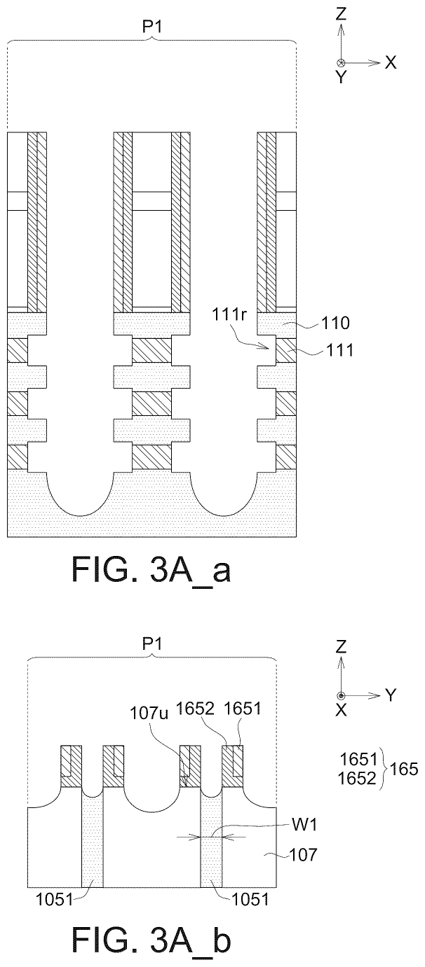

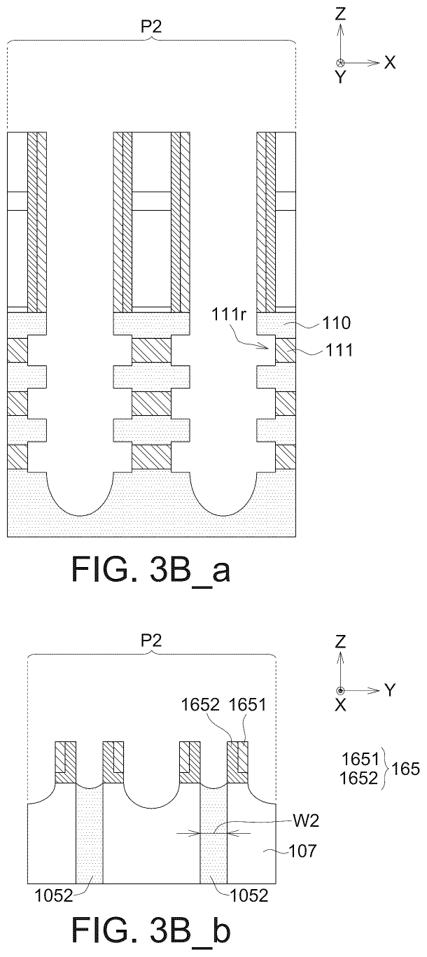

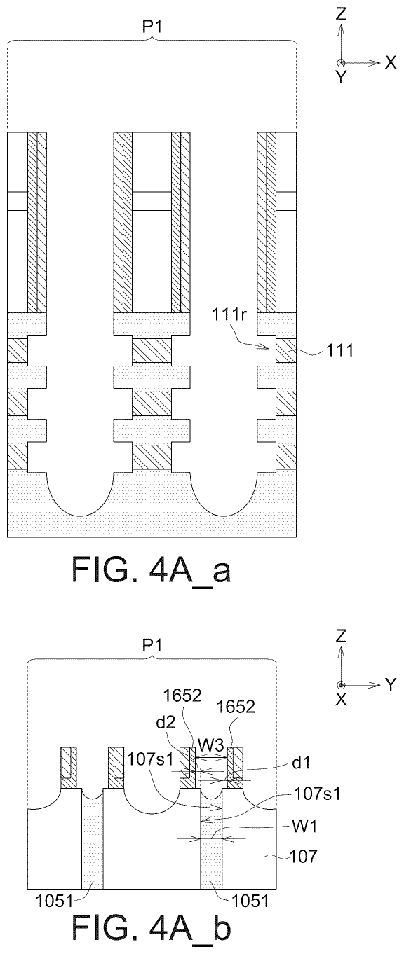

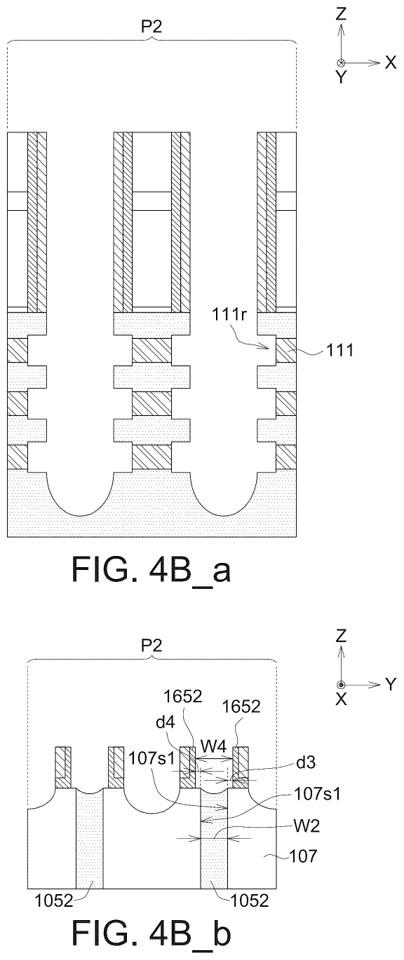

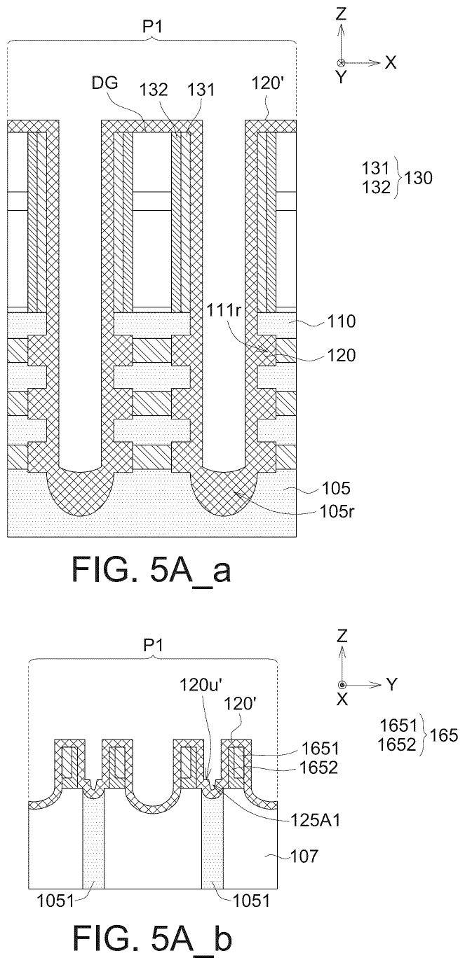

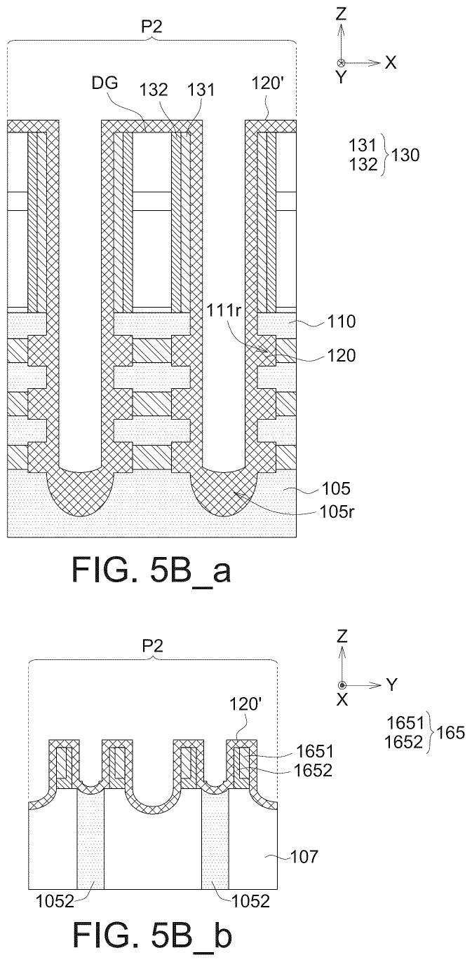

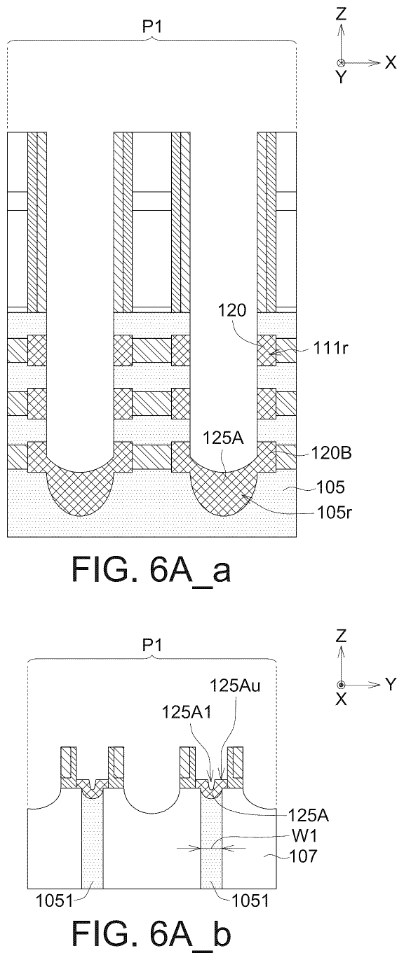

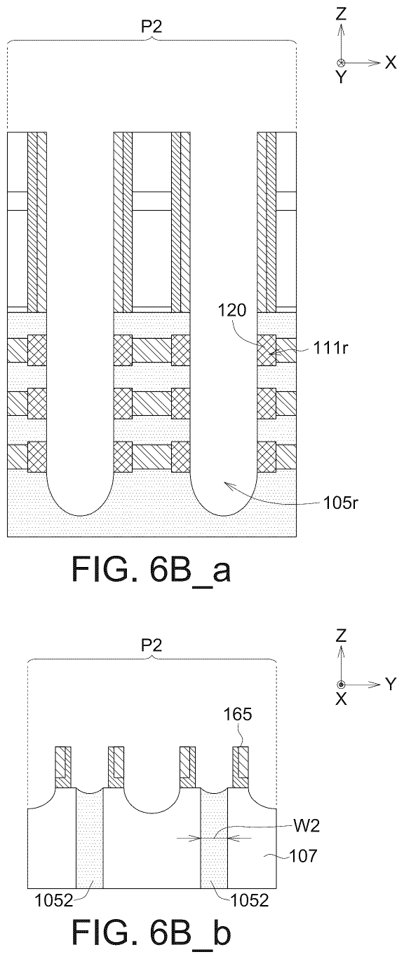

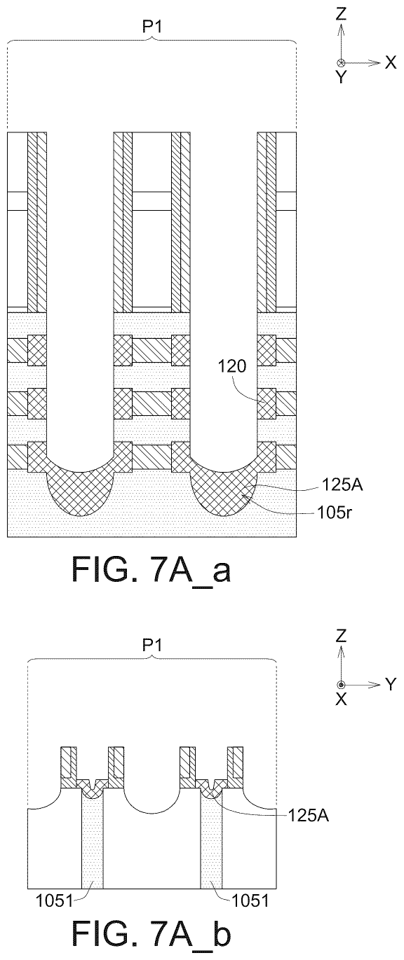

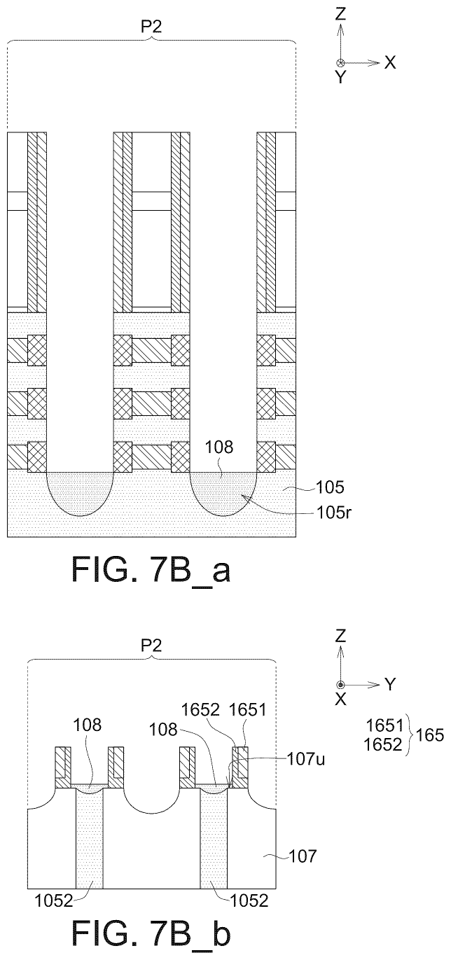

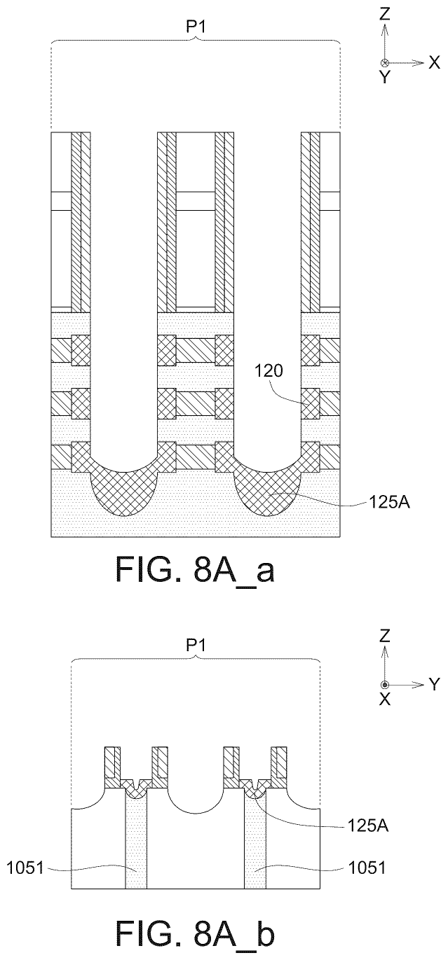

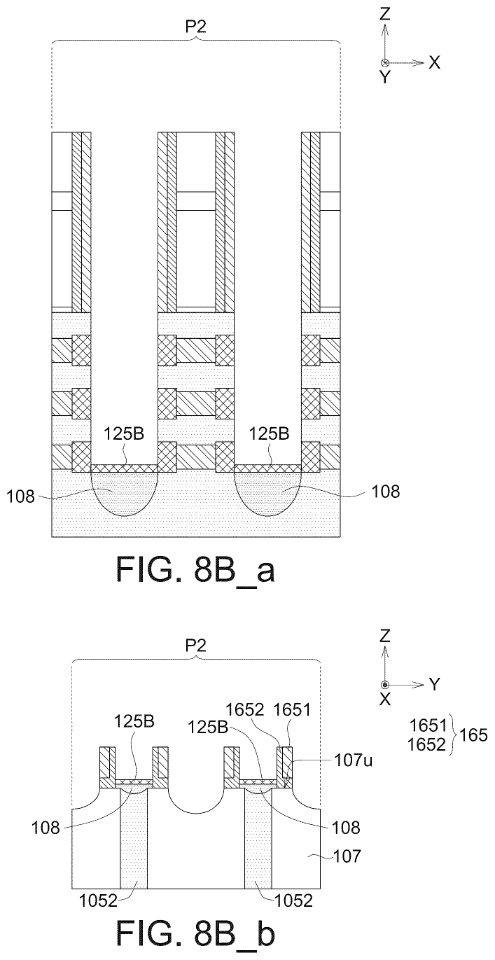

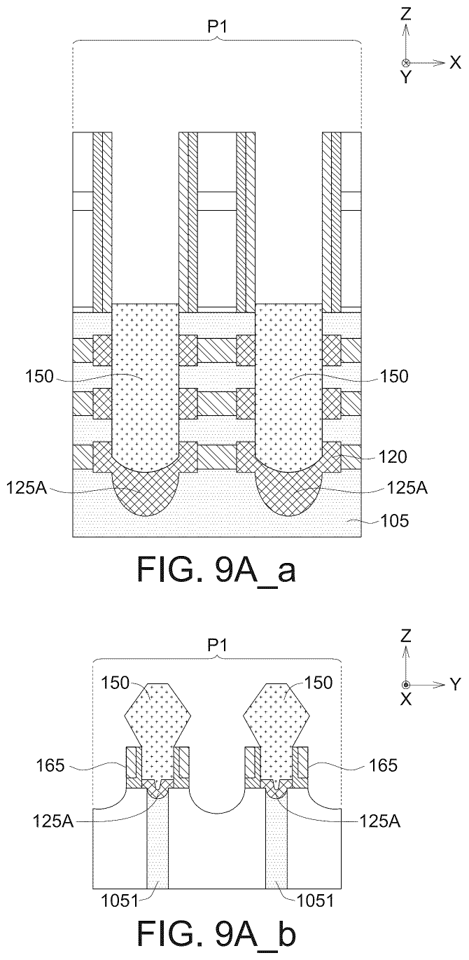

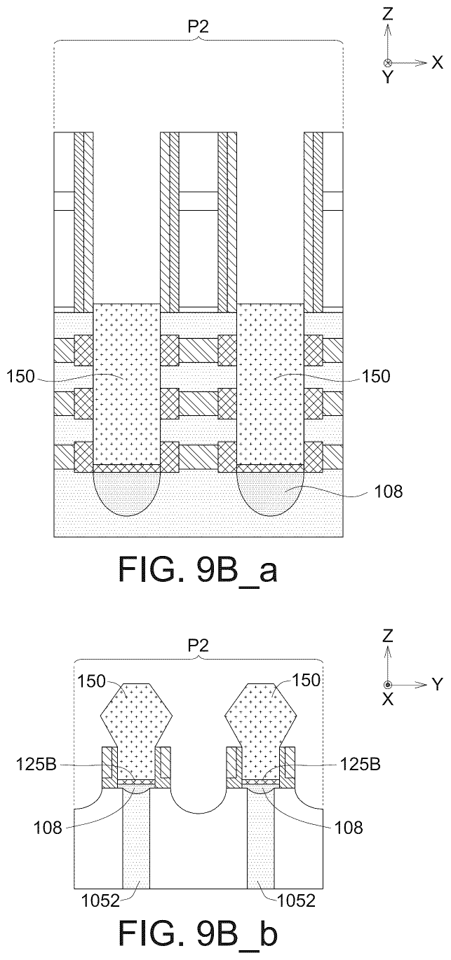

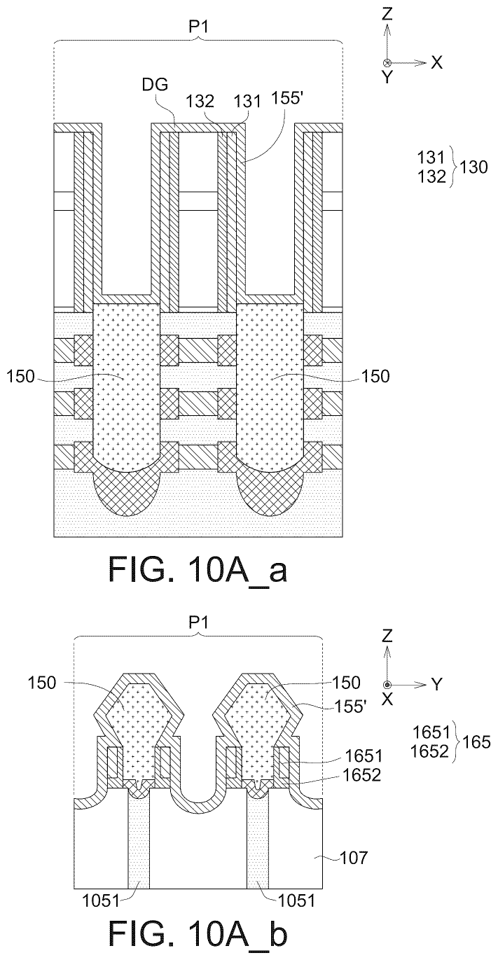

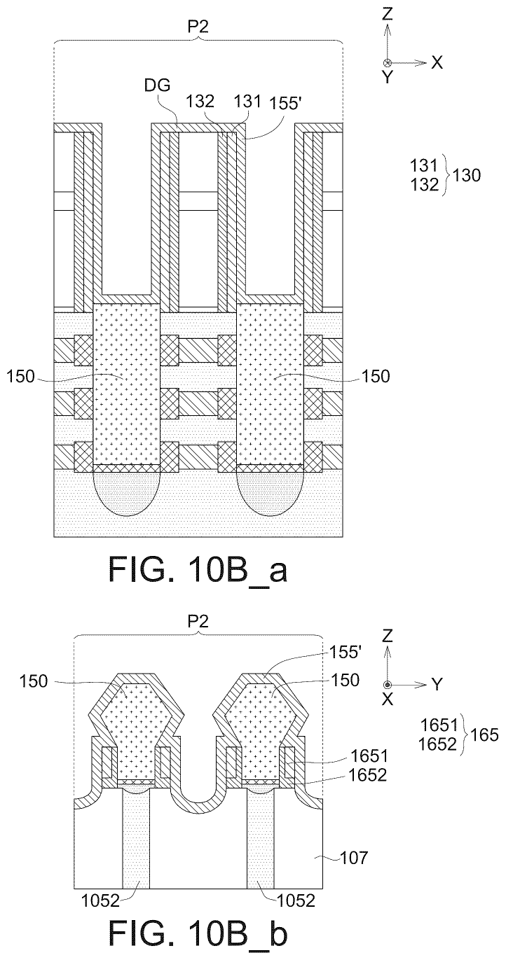

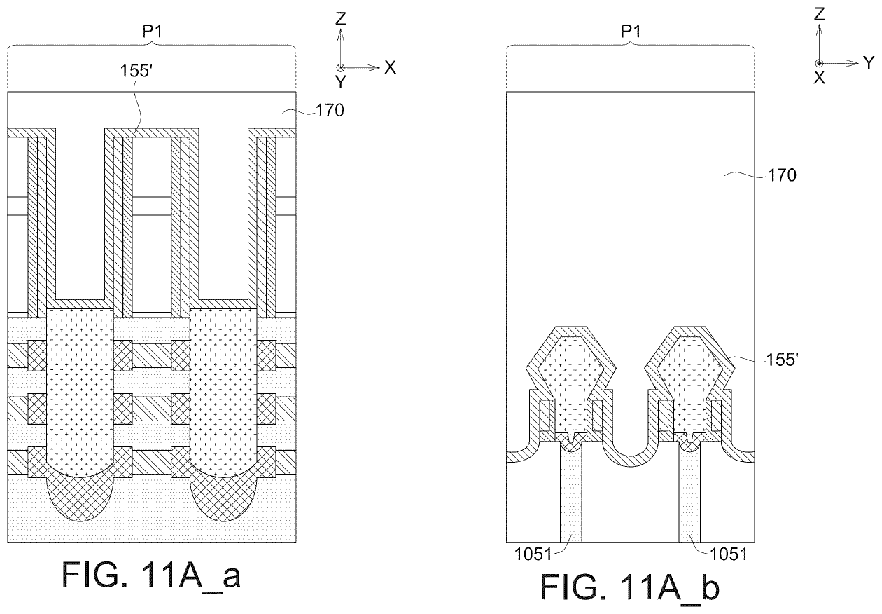

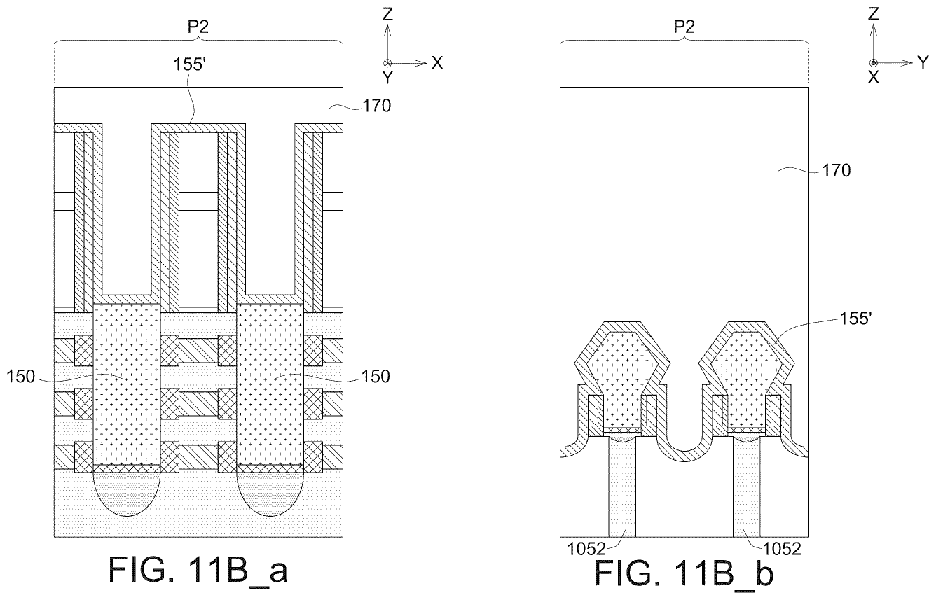

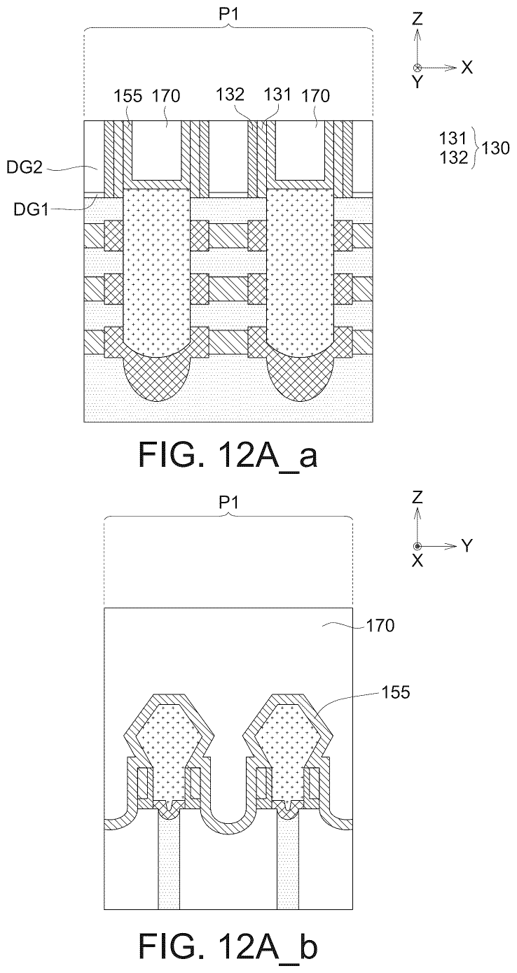

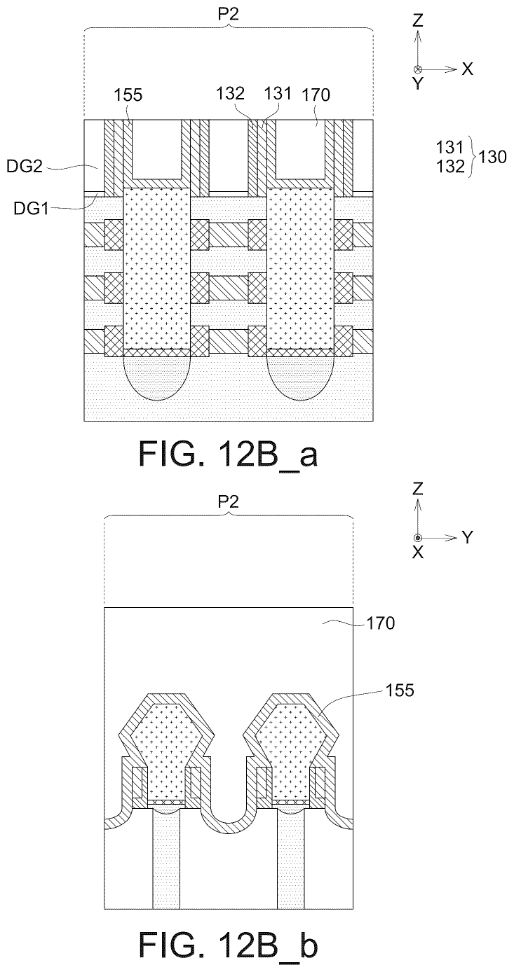

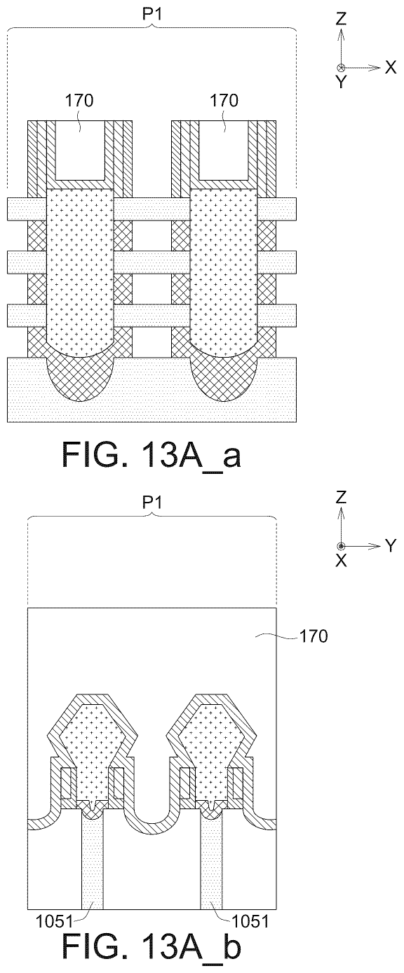

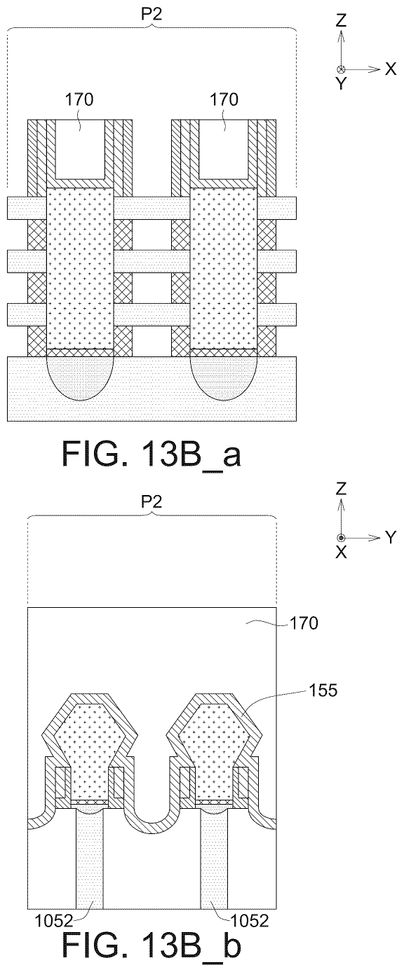

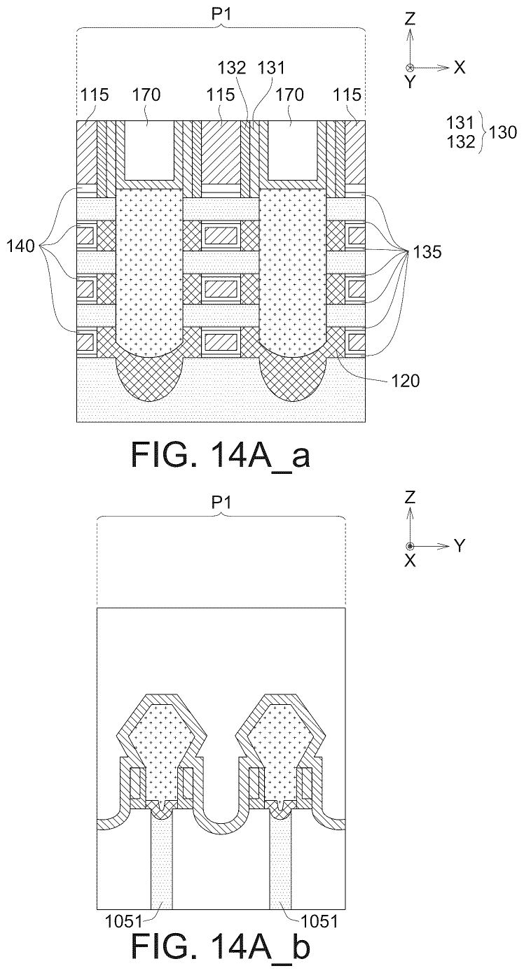

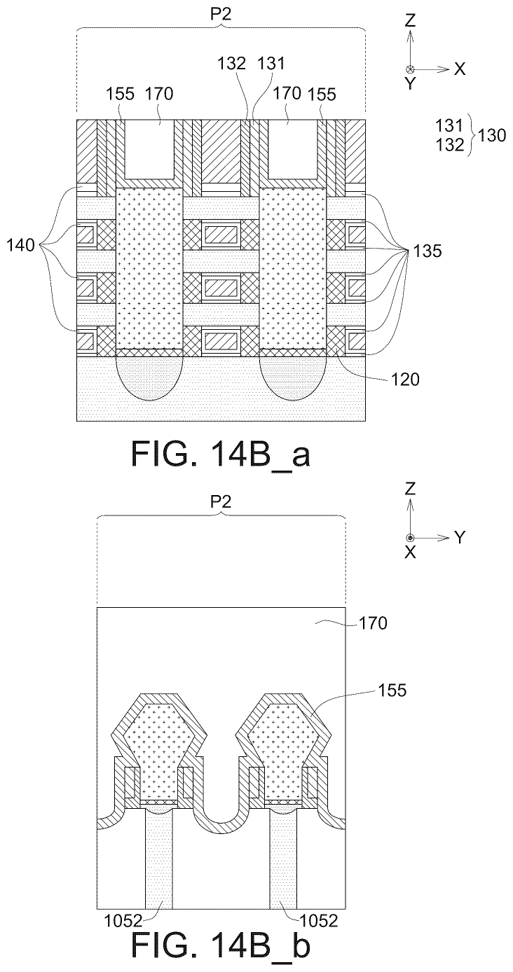

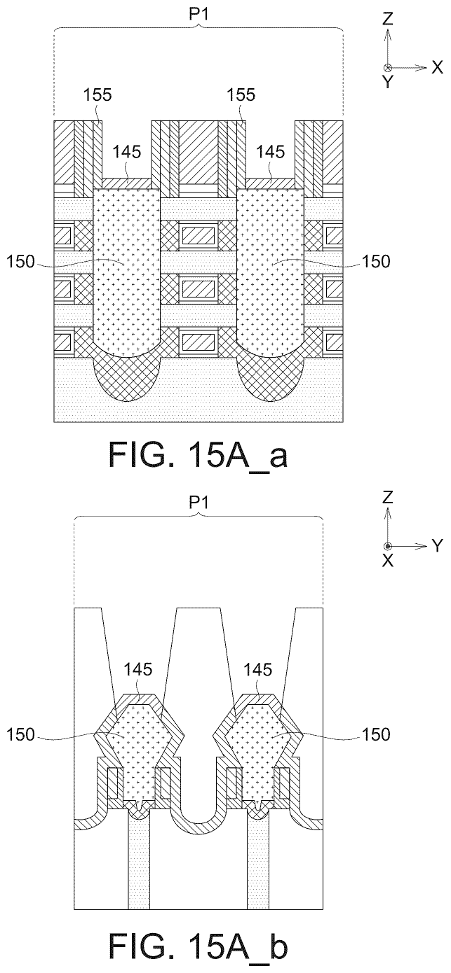

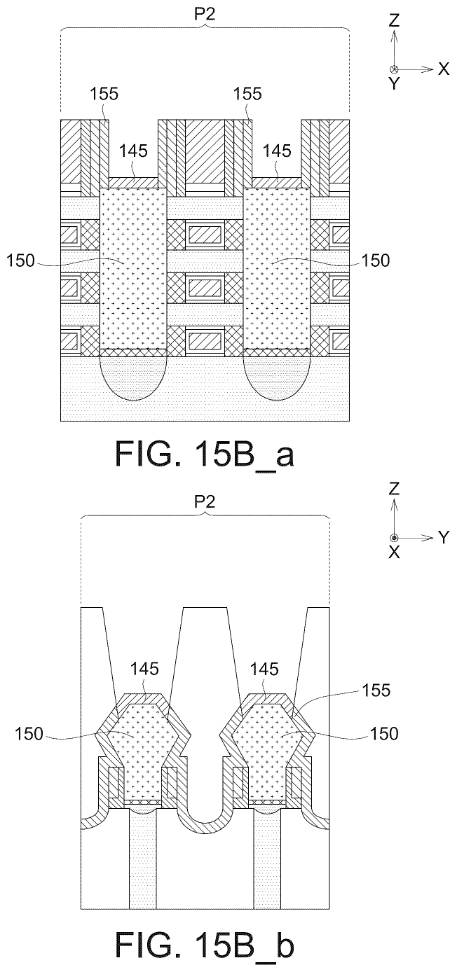

FIG. 2A_a to 15B_b illustrate schematic diagrams of manufacturing processes of the semiconductor structure 100 in FIG. 1A_a to 1B_b, wherein FIG. 2A_a, 2A_b, 3A_a, 3A_b, 4A_a, 4A_b, 5A_a, 5A_b, 6A_a, 6A_b, 7A_a, 7A_b, 8A_a, 8A_b, 9A_a, 9A_b, 10A_a, 10A_b, 11A_a, 11A_b, 12A_a, 12A_b, 13A_a, 13A_b, 14A_a, 14A_b, 15A_a and 15A_b illustrate manufacturing processes of the first local portion P1 of the semiconductor structure 100 in FIG. 1A_a to 1A_b, and FIG. 2B_a, 2B_b, 3B_a, 3B_b, 4B_a, 4B_b, 5B_a, 5B_b, 6B_a, 6B_b, 7B_a, 7B_b, 8B_a, 8B_b, 9B_a, 9B_b, 10B_a, 10B_b, 11B_a, 11B_b, 12B_a, 12B_b, 13B_a, 13B_b, 14B_a, 14B_b, 15B_a and 15B_b illustrate manufacturing processes of the second local portion P2 of the semiconductor structure 100 in FIG. 1B_a to 1B_b.

As illustrated in FIG. 2A_a to 2B_b, a plurality of the active channels 110 and a plurality of silicon germanium (SiGe) layers 111 are stacked on the substrate 105. Each active channel 110 is formed of, for example, silicon. One of the active channels 110 may be formed between adjacent two of the SiGe layers 111.

The dummy gate structures DG are formed on the active channels 110 by depositing, and then the second spacer 130 is formed on adjacent two sides of the corresponding dummy gate structure DG. The second spacer 130 includes the second portion 131 and the first portion 132, wherein the first portion 132 is disposed between the dummy gate structures DG and the second portion 131. In an embodiment, the second portion 131 may be formed of a material different from that of the first portion 132. The second portion 131 may be formed of one of SiO, SiN, SiOC, SiON, SiOCN, etc., the first portion 132 may be formed of another of SiO, SiN, SiOC, SiON, SiOCN, etc.

The dummy gate structure DG includes a dummy dielectric layer DG1, a dummy gate layer DG2, a mask layer DG3 and an oxide layer DG4. The dummy dielectric layer DG1 is formed on the active channel. The dummy dielectric layer DG1 is formed of a material including, for example, silicon oxide, silicon nitride, a combination thereof, or the like, and may be deposited or thermally grown according to acceptable techniques. The dummy gate layer DG2 is formed over the dummy dielectric layer DG1, and the mask layer DG3 is formed over the dummy gate layer DG2. The dummy gate layer DG2 may be deposited over the dummy dielectric layer DG1 and then planarized, such as by CMP. The mask layer DG3 may be deposited over the dummy gate layer DG2. The dummy gate layer DG2 may be a conductive or non-conductive material and may be selected from a group including amorphous silicon, polycrystalline-silicon (polysilicon), poly-crystalline silicon-germanium (poly-SiGe), metallic nitrides, metallic silicides, metallic oxides, and metals. The dummy gate layer DG2 may be deposited by physical vapor deposition (PVD), CVD, sputter deposition, or other techniques for depositing the selected material. The dummy gate layer DG2 may be formed of other materials that have a high etching selectivity from the etching of isolation regions. The mask layer DG3 may include, for example, silicon nitride, silicon oxynitride, or the like.

In FIG. 2A_a to 2A_b, in the first local portion P1, the substrate 105 includes a plurality of the first OD regions 1051 extending in X-axis. The first OD region 1051 has the first width W1 in the Y-axis. The oxide layer 107 on the adjacent two sides of the first OD regions 1051 is formed by using, for example, deposition. The oxide layer 107 is, for example, a STI. The first spacers 165 are formed on the upper surface 107u of oxide layer 107. The first spacer 165 includes the second portion 1651 and the first portion 1652. The second portion 1651 may be formed of a material different from that of the first portion 1652. In terms of material, the second portion 1651 may be formed of one of SiO, SiN, SiOC, SiON, SiOCN, etc., and the first portion 1652 may be formed of another of SiO, SiN, SiOC, SiON, SiOCN, etc.

In an embodiment, the first portion 132 and the first portion 1652 may be formed in the same deposition process, and the second portion 131 and the second portion 1651 may be formed in the same deposition process. The second portion 131 may be formed of a material same as that of the second portion 1651, and the first portion 132 may be formed a material same as that of the first portion 1652.

In FIG. 2B_a to 2B_b, in the second local portion P2, the substrate 105 includes a plurality of the second OD regions 1052 extending in X-axis. The second OD region 1052 has the second width W2 in the Y-axis. The second width W2 is greater than the first width W1. In an embodiment, the first width W1 is, for example, equal to or less than 10 nm, and the second width W2 is, for example, greater than 10 nm, 11 nm, 12 nm, or even greater.

As illustrated in FIG. 3A_a to 3B_b, a plurality of the recesses 111r in the SiGe layers 111 are formed by using, for example, etching. The recess 111r is recessed relative to a lateral surface of the active channel 110.

As illustrated in FIG. 4A_a to 4B_b, a portion of each of opposite two first portions 1652 is removed by using, for example, etching. The first portion 1652 is thinned to broaden the distance between the opposite two first portions 1652.

In FIG. 4A_a to 4A_b, in the first local portion P1, after removed, two opposite first portions 1652 are spaced from each other by the third width W3, and the third width W3 is greater than the first width W1. The difference between the opposite two first portions 1652 ranges between 2 μm and 8 μm.

In FIG. 4B_a to 4B_b, in the second local portion P2, after removed, two opposite first portion 1652 are spaced from each other by the fourth width W4, wherein the fourth width W4 is greater than the first width W2. The difference between the opposite two first portions 1652 ranges between 2 μm and 8 μm.

As illustrated in FIG. 5A_a to 5B_b, an inner spacer material 120′ covering the dummy gate structures DG, the second spacers 130, the active channels 110, the recesses 111r, the recesses 105r, the first OD regions 1051, the second OD regions 1052, the oxide layer 107, the first spacers 165 is formed by using, for example, deposition. The inner spacer material 120′ may include, for example, SiOCN, SiOC, SiCN, etc. In addition, the inner spacer material 120′ is disposed above the first OD region 1051 and has the upper surface 120u′ and the slot 125A1 extending from the upper surface 120u′ toward the first OD region 1051. In other words, due to the first width W1 of the first OD region 1051 is small enough, the slot 125A1 may be formed, and thus a portion (the first isolation layer 125A) of the inner spacer material 120′ may be retained in the subsequent trimming process.

As illustrated in FIG. 6A_a to 6B_b, a portion of the inner spacer material 120′ is removed (or trimmed) by using, for example, etching, to form a plurality of the inner spacers 120 within the recess 111r and the first isolation layer 125A within the recess 105r of the substrate 105. The first isolation layer 125A is connected with the bottommost inner spacers 120B.

In FIG. 6A_a to 6A_b, in the first local portion P1, due to the first OD region 1051 having the first width W1 which is small enough, the first isolation layer 125A may be retained in the recess 105r, wherein the first isolation layer 125A covers the first OD region 1051. The first isolation layer 125A is disposed above the first OD region 1051 and has the upper surface 125Au and the slot 125A1 extending from the upper surface 125Au of the first isolation layer 125A toward the first OD region 1051. Furthermore, due to the slot 125A1 being small enough, the first isolation layer 125A may be retained (the narrower the slot 125A1 is, the weaker the etching for the first isolation layer 125A is) in the trimming process.

In FIG. 6B_a to 6B_b, in the second local portion P2, due to the second OD region 1052 having the second width W2 which is greater enough, the inner spacer material 120′ over the first spacers 165 and the second OD regions 1052 and the oxide layer 107 in FIG. 5B_b may be removed by using, for example, etching. After removed, the second OD regions 1052 and the recess 105r of the substrate 105 are exposed.

As illustrated in FIG. 7A_a to 7B_b, the epitaxial silicon 108 within the recess 105r is formed by using, for example, epitaxy process.

In FIG. 7A_a to 7A_b, in the first local portion P1, due to the first isolation layer 125A covering the recess 105r of the substrate 105, the epitaxial silicon 108 is not formed within and on the recess 105r of the substrate 105, and thus there is no need to consider the height issues of the epitaxial silicon. In addition, due to the first isolation layer 125A covering the first OD region 1051, the epitaxial silicon 108 is not formed over the first OD region 1051.

In FIG. 7B_a to 7B_b, in the second local portion P2, due to the recess 105r being exposed, the epitaxial silicon 108 may be formed within the recess 105r. In addition, due to the second OD region 1052 being exposed, the epitaxial silicon 108 may be formed over the second OD region 1052 and a portion of the upper surface 107u of the oxide layer 107. The epitaxial silicon 108 may be contact with sidewalls of the first portions 1652 of the first spacer 165.

As illustrated in FIG. 8A_a to 8B_b, the second isolation layers 125B over the epitaxial silicon 108 are formed by using, for example, deposition, exposure, etching, development, etc.

In FIG. 8A_a to 8A_b, in the first local portion P1, due to the first isolation layer 125A being covered by a photoresist (not illustrated), the second isolation layers 125B is not formed over the first isolation layer 125A.

In FIG. 8B_a to 8B_b, in the second local portion P2, the second isolation layer 125B over the epitaxial silicon 108 may protrude relative to the upper surface 107u of the oxide layer 107. The second isolation layer 125B may be contact with sidewalls of the first portions 1652 of the first spacer 165.

As illustrated in FIG. 9A_a to 9B_b, a plurality of the epitaxies 150 may be formed in a space between adjacent two dummy gate structures DG by using, for example, epitaxy process. Each epitaxy 150 may be N-type epitaxy or P-type epitaxy. Each epitaxy 150 may be a source or a drain of a transistor.

In FIG. 9A_a to 9A_b, in the first local portion P1, the epitaxies 150 may be formed over the first isolation layer 125A. The first isolation layer 125A between the epitaxy 150 and the substrate 105 may increase the isolation between the adjacent two of the epitaxies 150.

In FIG. 9B_a to 9B_b, in the second local portion P2, the epitaxies 150 may be formed over the second isolation layer 125B. The second isolation layer 125B between the epitaxy 150 and the epitaxial silicon 108 (or the substrate 105) may increase the isolation between the adjacent two of the epitaxies 150.

As illustrated in FIG. 10A_a to 10B_b, a CESL material 155′ over the second spacers 130, the epitaxies 150, the first spacers 165, upper surfaces of the dummy gate structures DG and the oxide layer 107 are formed by using, for example, deposition, such as chemical vapor deposition (CVD), Plasma-Enhanced Chemical Vapor Deposition (PECVD), ALD (atomic layer deposition), or the like. The CESL material 155′ may be formed of a material including, for example, a dielectric material, such as silicon nitride, silicon oxide, silicon oxynitride, or the like.

As illustrated in FIG. 11A_a to 11B_b, the ILD 170 covering the CESL material 155′ is formed by using, for example, deposition, such as CVD, PECVD, or flowable chemical vapor deposition (FCVD), or the like. The ILD 170 may be formed of a dielectric including, for example, phospho-silicate glass (PSG), boro-silicate glass (BSG), boron-doped phospho-silicate glass (BPSG), undoped silicate glass (USG), or the like. Other insulation materials formed by any acceptable process may be used.

As illustrated in FIG. 12A_a to 12B_b, the ILD 170, the CESL material 155′ and the dummy gate structures DG may be planarized by using, for example, Chemical-Mechanical Polishing (CMP). After being planarized, the CESL material 155′ forms a plurality of the CESLs 155, and the mask layer DG3 and the oxide layer DG4 of the dummy gate structure DG may be removed, and the dummy dielectric layer DG1 and the dummy gate layer DG2 may be retained. In addition, after being planarized, the dummy gate layer DG, the second portion 131, the first portion 132 and the ILD 170 may form, for example, a planarized surface.

As illustrated in FIG. 13A_a to 13B_b, the SiGe layers 111 and the dummy dielectric layer DG1 and the dummy gate layer DG2 of the dummy gate structure DG may be removed by using, for example, an anisotropic dry etch process. Furthermore, the etching process could include a dry etch process using reaction gas(es) that selectively etch the dummy gate structures DG at a faster rate than the ILD 170. In an embodiment, before the removal, a helmet (not illustrated) may be formed on the ILD 170, by using for example, etching/deposition, to block the removal for the dummy gate structures DG. In addition, the SiGe layers 111 also be removed by using, for example, etching. After the dummy gate structures DG and the SiGe layers 111 are removed, the active channels 110 are exposed.

As illustrated in FIG. 14A_a to 14B_b, the first dielectric layers 135 are formed on the active channels 110 by using, for example, deposition. Then, the second dielectric layer 140 over the inner spacer 120 and the first dielectric layers 135 are formed by using, for example, deposition. Then, the metal gate 115 over the second dielectric layer 140 and the second spacer 130 is formed by a process such as ALD, CVD, PVD, remote plasma CVD (RPCVD), plasma enhanced CVD (PECVD), metal-organic CVD (MOCVD), sputtering, electroplating, other suitable processes, or the like.

The metal gate 115 may be formed of a work function metal. The work function metal may be an N-type or P-type work function layer. Exemplary P-type work function metals include TiN, TaN, Ru, Mo, Al, WN, ZrSi2, MoSi2, TaSi2, NiSi2, WN, other suitable P-type work function materials, or combinations thereof. Exemplary N-type work function metals include Ti, Ag, TaAl, TaAlC, TiAlN, TaC, TaCN, TaSiN, Mn, Zr, other suitable N-type work function materials, or combinations thereof. The work function layer may contain multiple layers.

As illustrated in FIG. 15A_a to 15B_b, a portion of the ILD 170 and a bottom portion of the CESL 155 are removed to expose the epitaxies 150 by using, for example, deposition, exposure, etching, development, etc. Then, the silicide layers 145 over the exposed epitaxies 150 are formed by using, for example, deposition.

Then, the contacts 160 in FIG. 1A_a and 1B_a are formed over the CESL 155 and the epitaxies 150. The contacts 160 may be formed of a metal including the material the same as or similar to that of the metal gate 115.

The above description of illustrated implementations of the disclosure, including what is described in the Abstract, is not intended to be exhaustive or to limit the disclosure to the precise forms disclosed. While specific implementations of, and examples for, the disclosure are described herein for illustrative purposes, various equivalent modifications are possible within the scope of the disclosure, as those skilled in the relevant art will recognize.

These modifications may be made to the disclosure in light of the above detailed description. The terms used in the following claims should not be construed to limit the disclosure to the specific implementations disclosed in the specification and the claims. Rather, the scope of the disclosure is to be determined entirely by the following claims, which are to be construed in accordance with established doctrines of claim interpretation.

According to the present disclosure, a semiconductor structure includes a smaller OD region and a larger OD region. In the smaller OD region, a first isolation layer is disposed in a recess of a substrate and connected with the bottommost inner spacer. In the larger OD region, a second isolation layer is disposed above an epitaxial silicon which is disposed in the recess of the substrate. Accordingly, it may increase AC performance and/or the isolation between the adjacent two of the epitaxies (reducing the current leakage).

Example embodiment 1: a semiconductor structure includes a substrate, plurality of active channels, a metal gate, a plurality of inner spacers and a first isolation layer. The substrate has an upper surface and a recess recessed relative to the upper surface. The active channels are vertically stacked on the upper surface of the substrate. The metal gate is disposed on the active channels. The inner spacers are disposed on a lateral surface of the metal gate. The first isolation layer is disposed within the recess and connected with the bottommost inner spacer. The first isolation layer protrudes relative to the upper surface of the substrate.

Example embodiment 2 based on Example embodiment 1: the first isolation layer and the bottommost inner spacer are formed of the same material.

Example embodiment 3 based on Example embodiment 1: the substrate includes a first oxide definition (OD) region having a lateral surface, and further includes an oxide layer on the lateral surface of the first OD region and having an upper surface. The first isolation layer protrudes relative to the upper surface of the oxide layer.

Example embodiment 4 based on Example embodiment 3: the first OD region has a width less than 10 nm.

Example embodiment 5 based on Example embodiment 1: the substrate includes a first OD region having a lateral surface, and the semiconductor structure further includes an oxide layer and a first spacer. The oxide layer is disposed on a lateral surface of the region and has an upper surface and a lateral surface facing the lateral surface of the first OD region. The first spacer is disposed on the upper surface of the oxide layer. The first spacer is spaced from the lateral surface of the oxide layer by a distance.

Example embodiment 6 based on Example embodiment 5: the distance ranges between 1 micrometers (μm) and 4 μm.

Example embodiment 7 based on Example embodiment 5: the first isolation layer is contact with the first spacer.

Example embodiment 8 based on Example embodiment 5: the first spacer includes a first portion and a second portion, and the first portion of the first spacer is disposed between the first isolation layer and the second portion of the first spacer; and the semiconductor structure further includes a second spacer. The second spacer is disposed above the active channels and on a lateral surface of the metal gate, and includes a first portion and a second portion, wherein the first portion of the second spacer is disposed between the metal gate and the second portion of the second spacer. The first portion of the second spacer and the first portion of the first spacer are formed of the same material, and the second portion of the second spacer and the second portion of the first spacer are formed of the same material.

Example embodiment 9 based on Example embodiment 1: the substrate includes a first OD region, and the first isolation layer is disposed above the first OD region and has an upper surface and a slot extending from the upper surface of the isolation layer toward the first OD region.

Example embodiment 10 based on Example embodiment 9: the semiconductor structure further includes an epitaxy filling the slot.

Example embodiment 11 based on Example embodiment 1: the substrate further includes a second OD region; the semiconductor structure further includes an oxide layer, a first spacer and a semiconductor region. The oxide layer is disposed on a lateral surface of the second OD region and has an upper surface and a lateral surface facing the lateral surface of the second OD region. The first spacer is disposed on the upper surface of the oxide layer. The semiconductor region is disposed above the second OD region and protrudes relative to the upper surface of the oxide layer.

Example embodiment 12 based on Example embodiment 11: the second OD region has a width greater than 12 nm.

Example embodiment 13: a semiconductor structure includes a substrate, an oxide layer, a plurality of active channels, a metal gate, a plurality of inner spacers, a first isolation layer, a semiconductor region and a second isolation layer. The substrate includes a first OD region and a second OD region, wherein the first OD region has a first width, the second OD region has a second width less than the first width, wherein the substrate has an upper surface. The oxide layer is disposed on lateral surfaces of the first OD region and the second OD region and has an upper surface. The active channels are vertically stacked on the upper surface of the substrate. The metal gate is disposed on the active channels. The inner spacers are disposed on a lateral surface of the metal gate. The first isolation layer is disposed over the first OD region, connected with the bottommost inner spacer and protrudes relative to the upper surface of the oxide layer. The semiconductor region is disposed over the second OD region and protrudes relative to the upper surface of the oxide layer. The second isolation layer is disposed over the semiconductor region and protrudes relative to the upper surface of the oxide layer.

Example embodiment 14 based on Example embodiment 13: the semiconductor structure further includes a first spacer. The first spacer is disposed on the upper surface of the oxide layer. The first spacer is spaced from a lateral surface of the oxide layer by a distance.

Example embodiment 15 based on Example embodiment 14: the distance ranges between 1 μm and 4 μm.

Example embodiment 16 based on Example embodiment 13: the first isolation layer has an upper surface and a slot extending from the upper surface of the first isolation layer toward the first OD region.

Example embodiment 17: a manufacturing method for a semiconductor structure includes the following steps: forming a plurality of active channels vertically stacked on an upper surface of the substrate, wherein the substrate has an upper surface and a recess recessed relative to the upper surface; forming a metal gate on the active channels; forming a plurality of inner spacers on a lateral surface of the metal gate; and forming a first isolation layer within the recess and connected with the bottommost inner spacer, wherein the first isolation layer protrudes relative to the upper surface of the substrate.

Example embodiment 18 based on Example embodiment 17: forming the inner spacers and forming the first isolation layer are completed in the same etching process.

Example embodiment 19 based on Example embodiment 17: the manufacturing method further includes: forming an inner spacer material to cover the active channels and the first OD region, wherein the inner spacer material has an upper surface and a slot extending from the upper surface of the inner spacer material toward the first OD region.

Example embodiment 20 based on Example embodiment 19: the manufacturing method further includes: forming an epitaxy to fill the slot.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor structure, comprising:
a substrate having an upper surface and a recess recessed relative to the upper surface;
a plurality of active channels vertically stacked on the upper surface of the substrate;
a metal gate on the active channels;
a plurality of inner spacers on a lateral surface of the metal gate; and
a first isolation layer within the recess and connected with the bottommost inner spacer;
wherein the first isolation layer protrudes relative to the upper surface of the substrate.

2. The semiconductor structure according to claim 1, wherein the first isolation layer and the bottommost inner spacer are formed of the same material.

3. The semiconductor structure according to claim 1, wherein the substrate comprises a first oxide definition (OD) region having a lateral surface, and further comprises:
an oxide layer on the lateral surface of the first OD region and having an upper surface;
wherein the first isolation layer protrudes relative to the upper surface of the oxide layer.

4. The semiconductor structure according to claim 3, wherein the first OD region has a width less than 10 nm.

5. The semiconductor structure according to claim 1, wherein the substrate comprises a first OD region having a lateral surface, and the semiconductor structure further comprises:
an oxide layer on a lateral surface of the region and having an upper surface and a lateral surface facing the lateral surface of the first OD region; and
a first spacer on the upper surface of the oxide layer;
wherein the first spacer is spaced from the lateral surface of the oxide layer by a distance.

6. The semiconductor structure according to claim 5, wherein the distance ranges between 1 micrometers (μm) and 4 μm.

7. The semiconductor structure according to claim 5, wherein the first isolation layer is contact with the first spacer.

8. The semiconductor structure according to claim 5, wherein the first spacer comprises a first portion and a second portion, and the first portion of the first spacer is disposed between the first isolation layer and the second portion of the first spacer; and the semiconductor structure further comprises:
a second spacer above the active channels and on a lateral surface of the metal gate, and comprising a first portion and a second portion, wherein the first portion of the second spacer is disposed between the metal gate and the second portion of the second spacer;
wherein the first portion of the second spacer and the first portion of the first spacer are formed of the same material, and the second portion of the second spacer and the second portion of the first spacer are formed of the same material.

9. The semiconductor structure according to claim 1, wherein the substrate comprises a first OD region, and the first isolation layer is disposed above the first OD region and has an upper surface and a slot extending from the upper surface of the isolation layer toward the first OD region.

10. The semiconductor structure according to claim 9, further comprising:
an epitaxy filling the slot.

11. The semiconductor structure according to claim 1, wherein the substrate further comprises a second OD region; the semiconductor structure further comprises:
an oxide layer on a lateral surface of the second OD region and having an upper surface and a lateral surface facing the lateral surface of the second OD region;
a first spacer on the upper surface of the oxide layer; and
a semiconductor region above the second OD region and protruding relative to the upper surface of the oxide layer.

12. The semiconductor structure according to claim 11, wherein the second OD region has a width greater than 12 nm.

13. A semiconductor structure, comprising:
a substrate comprising a first OD region and a second OD region, wherein the first OD region has a first width, the second OD region has a second width less than the first width, wherein the substrate has an upper surface;
an oxide layer on lateral surfaces of the first OD region and the second OD region and having an upper surface;
a plurality of active channels vertically stacked on the upper surface of the substrate;
a metal gate on the active channels;
a plurality of inner spacers on a lateral surface of the metal gate;
a first isolation layer over the first OD region, connected with the bottommost inner spacer and protruding relative to the upper surface of the oxide layer;
a semiconductor region over the second OD region and protruding relative to the upper surface of the oxide layer; and
a second isolation layer over the semiconductor region and protruding relative to the upper surface of the oxide layer.

14. The semiconductor structure according to claim 13, further comprising:
a first spacer on the upper surface of the oxide layer;
wherein the first spacer is spaced from a lateral surface of the oxide layer by a distance.

15. The semiconductor structure according to claim 14, wherein the distance ranges between 1 μm and 4 μm.

16. The semiconductor structure according to claim 13, wherein the first isolation layer has an upper surface and a slot extending from the upper surface of the first isolation layer toward the first OD region.

17. A manufacturing method for a semiconductor structure, comprising:
forming a plurality of active channels vertically stacked on an upper surface of the substrate, wherein the substrate has an upper surface and a recess recessed relative to the upper surface;
forming a metal gate on the active channels;
forming a plurality of inner spacers on a lateral surface of the metal gate; and
forming a first isolation layer within the recess and connected with the bottommost inner spacer, wherein the first isolation layer protrudes relative to the upper surface of the substrate.

18. The manufacturing method according to claim 17, wherein forming the inner spacers and forming the first isolation layer are completed in the same etching process.

19. The manufacturing method according to claim 17, further comprising:
forming an inner spacer material to cover the active channels and the first OD region, wherein the inner spacer material has an upper surface and a slot extending from the upper surface of the inner spacer material toward the first OD region.

20. The manufacturing method according to claim 19, further comprising:
forming an epitaxy to fill the slot.
